(19) United States
(12) Patent Application Publication
(10) Pub. No.: US 2012/0325307 A1
(43) Pub. Date: Dec. 27, 2012

(54) LOW BOW ALUMINUM PASTE WITH AN ALKALINE EARTH METAL SALT ADDITIVE FOR SOLAR CELLS

(75) Inventors: ZHIGANG RICK LI, Hockessin, DE (US); LIANG LIANG, Hockessin, DE (US); RAJ G. RAJENDRAN, Hockessin, DE (US)

(73) Assignee: E. I. DU PONT DE NEMOURS AND COMPANY, Wilmington, DE (US)

(21) Appl. No.: 13/327,811

(22) Filed: Dec. 16, 2011

Related U.S. Application Data
(63) Continuation-in-part of application No. 12/969,908, filed on Dec. 16, 2010.

(51) Int. Cl. H01B 1/22; H01L 31/18; H01L 31/0224

(52) U.S. Cl. 136/256; 252/512; 438/98; 257/E31.124

(57) ABSTRACT

Disclosed are aluminum paste compositions for forming an aluminum back electrode, processes to form aluminum back electrode of solar cells, and the solar cells so-produced. The aluminum paste composition has particulate aluminum and an additive wherein the additive is a salt of an alkaline earth metal ion and an organic counterion dispersed in an organic vehicle.

### CROSS REFERENCE TO RELATED APPLICATIONS

This application claims the benefit of U.S. patent application Ser. No. 12/969,908 filed on Dec. 16, 2010.

### FIELD OF THE INVENTION

The present invention relates to aluminum paste compositions and their use as a backside conductive paste in solar cells.

### TECHNICAL BACKGROUND

Currently, most electric power-generating solar cells are silicon solar cells. A conventional silicon solar cell structure has a large area p-n junction made from a p-type silicon wafer, a negative electrode that is typically on the front-side or sun-side of the cell and a positive electrode on the back-side. It is well-known that radiation of an appropriate wavelength falling on a p-n junction of a semiconductor body serves as a source of external energy to generate hole-electron pairs in that body. The potential difference that exists at a p-n junction causes holes and electrons to move across the junction in opposite directions and thereby gives rise to flow of an electric current that is capable of delivering power to an external circuit.

Process flow in mass production of solar cells is generally aimed at achieving maximum simplification and minimization of manufacturing costs. Electrodes are typically made using methods such as screen printing from a metal paste. During the formation of a silicon solar cell, an aluminum paste is generally screen printed and dried on the back-side of the silicon wafer. The wafer is then fired at a temperature above the melting point of aluminum to form an aluminum-silicon melt. Subsequently, during the cooling phase, an epitaxially grown layer of silicon is formed that is doped with aluminum. However, a major problem in using aluminum paste for creating the back-side contact is “wafer bowing” or deformation of the cell due to mismatch of the co-efficient of thermal expansion (CTE) between aluminum (˜23×10⁻⁶/K) and silicon (˜3×10⁻⁶/K). Furthermore, in an attempt to reduce total manufacturing cost of the silicon solar cells, thinner silicon wafers are being used. Currently, a typical silicon wafer for solar cell is 200 microns thick and the industry trend is toward thinner wafer to reduce the overall module cost. As the silicon wafer thickness decreases, the cell deformation (“wafer bowing”) increases and further processing of cells becomes cumbersome resulting in poor process yielding.

Hence, there is a need for back-side aluminum paste compositions to decrease bowing of the silicon solar cells.

US 2007/0079868 discloses aluminum thick film compositions which can be used in forming aluminum back electrodes of silicon solar cells. Apart from particulate aluminum, an organic medium as vehicle and glass frit as an optional constituent, the aluminum thick film compositions comprise amorphous silicon dioxide as an essential constituent. The amorphous silicon dioxide serves in particular to reduce the bowing behavior of the silicon solar cells.

Similarly, US 2009/0255583A1 discloses aluminum thick film compositions which can be used in forming aluminum back electrodes of silicon solar cells. Apart from particulate aluminum, an organic medium as vehicle and glass frit, silicon dioxide and zinc-organic component as an optional constituents, the aluminum thick film compositions comprise tin-organic component as an essential constituent. The tin-organic component serves in particular to reduce the bowing behavior of the silicon solar cells.

### SUMMARY OF THE INVENTION

Disclosed are aluminum paste compositions comprising:

a) 0.050-12.7% by weight of an additive, the additive comprising a salt of an alkaline earth metal ion and an organic counterion, wherein the organic counterion is selected from the group consisting of carboxylates, phenylates, and resonates;

b) 42-85% by weight of an aluminum powder, such that the weight ratio of aluminum powder to the additive is in the range of 5:1 to about 999:1; and

c) an organic vehicle,

wherein the amounts in % by weight are based on the total weight of the aluminum paste composition.

Also disclosed herein are solar cells comprising:

(a) a p-type silicon substrate comprising a p-type region sandwiched between an n-type region and a p+ layer;

(b) an aluminum back electrode disposed on the p+ layer, wherein the aluminum back electrode comprises 0.05-13.4% by weight of an additive and its decomposition products(s), the additive comprising a salt of an alkaline earth metal ion and an organic counterion and 86.6-99.95 by weight of aluminum, based on the total weight of the aluminum back electrode,

wherein the organic counterion is selected from the group consisting of carboxylates, phenylates, and resonates, and

wherein the decomposition products of the additive comprises alkaline earth metal oxide and alkaline earth metal hydroxide; and

(c) a metal front electrode disposed over a portion of the n-type region.

Also disclosed herein are processes for forming a silicon solar cell, comprising:

(a) applying an aluminum paste composition on a back-side of a p-type silicon substrate, the aluminum paste composition comprising:
(i) 0.05-12.7% by weight of an additive, the additive comprising a salt of an alkaline earth metal ion and an organic counterion, wherein the organic counterion is selected from the group consisting of carboxylates, phenylates, and resonates,
(ii) 42-85% by weight of an aluminum powder, such that the weight ratio of aluminum powder to the additive is in the range of 5:1 to about 999:1, and
(iii) an organic vehicle,
wherein the amounts in % by weight are based on the total weight of the aluminum paste composition;

(b) applying a metal paste on a front-side of the p-type silicon substrate, the front-side being opposite to the back-side; and

(c) firing the p-type silicon substrate after the application of the aluminum paste at a peak temperature in the range of 600-980° C.

### BRIEF DESCRIPTION OF THE FIGURES

FIGS. 1A-F illustrate an exemplary process for the fabrication of a silicon solar cell.

FIGS. 2A-D illustrate an exemplary process for manufacturing a silicon solar cell using a back-side aluminum paste of the present invention.

FIG. 3 is a cross-sectional SEM image of a portion of the aluminum particulate layer of a solar cell made using an aluminum paste composition with calcium carbonate as an additive, in accordance with the present invention.

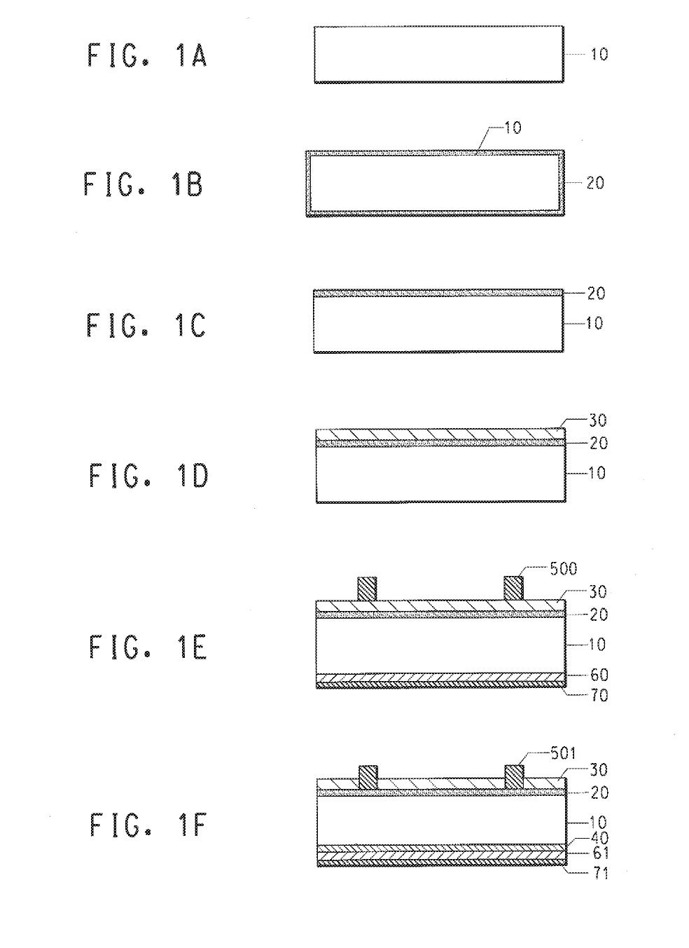

Reference numerals shown in FIGS. 1A-F, 2A-D, and 3 are explained below.
10: p-type silicon wafer
20: n-type diffusion layer
30: antireflective coating, for example, SiNx, TiOx, SiOx
40: p+ layer (back surface field, BSF)
60: back-side aluminum paste
61: aluminum back electrode (obtained by firing back-side aluminum paste)
70: back-side silver or silver/aluminum paste
71: silver or silver/aluminum back electrode (obtained by firing back-side silver or silver/aluminum paste)
500: front-side silver paste
501: silver front electrode (obtained by firing front-side silver paste)
102: silicon substrate (silicon wafer)
104: metal front electrode
106: back-side aluminum paste for a first back-side electrode
108: electroconductive paste for a second back-side electrode
110: first back-side electrode (aluminum back electrode)
112: second back-side electrode (silver or silver/aluminum electrode)
365: aluminum particles
366: silicon particles
371: calcium carbonate particle
372: calcium oxide and/or calcium hydroxide

### DETAILED DESCRIPTION OF THE INVENTION

Disclosed are aluminum paste compositions comprising an additive, the additive comprising a salt of an alkaline earth metal ion and an organic counterion, aluminum powder, and, an organic vehicle (organic medium).

In an embodiment, the additive comprising a salt of an alkaline earth metal ion and an organic counterion is a liquid. As used herein, the term, “salt of an alkaline earth metal ion and an organic counterion” is used interchangeably with “alkaline earth metal salt”, “alkaline earth metallorganic compound”, “alkaline earth metal-organic compound”, and “alkaline earth metal-organic component”. The term “salt of an alkaline earth metal ion and an organic counterion” as used herein refers to both solid and liquid forms of alkaline earth metallorganic compounds.

In the context of the present invention, the term “salt of an alkaline earth metal ion and an organic counterion” includes such metal compounds that comprise at least one organic moiety in the molecule. “An additive comprising a salt of an alkaline earth metal ion and an organic counterion” is stable or essentially stable, for example, in the presence of atmospheric oxygen or air humidity, under the conditions prevailing during preparation, storage, and application of the aluminum pastes of the present invention. The same is true under the application conditions, in particular, under those conditions prevailing during screen printing of the aluminum pastes onto the back-side of the silicon wafers. However, during firing of the aluminum pastes the organic counterion portion of the “salt of an alkaline earth metal ion and an organic counterion” will or will essentially be removed, for example, burned and/or carbonized. The alkaline earth metal ion after firing is frequently present as an oxide and/or hydroxide.

Examples of suitable salts of an alkaline earth metal ion and an organic counterion include, in particular, alkaline earth metal carbonates, alkaline earth metal resinates (calcium salts of acidic resins, in particular, resins with carboxyl groups such as octanoates) and alkaline earth metal carboxylates (calcium carboxylic acid salts) and mixtures thereof. Suitable salts of an alkaline earth metal ion and an organic counterion also include mixed alkaline earth metal salts with organic counterions, for example, calcium magnesium carbonate. Suitable salts of an alkaline earth metal ion and an organic counterion also include mixtures of salts, for example, a mixture of calcium carbonate and calcium oxalate.

The “salt of an alkaline earth metal ion and an organic counterion” may be present in the aluminum pastes of the present invention in a proportion corresponding to a salt contribution of 0.05-12.7% or 0.1-6% by weight, based on the total weight of the aluminum paste composition.

In an embodiment, the alkaline earth metal carbonate, is present in the range of 0.05-12.7% or 0.1-6% by weight, based on total weight of the aluminum paste composition.

Suitable aluminum powder includes aluminum particles such as, flake aluminum, spherical aluminum, nodular aluminum, irregularly-shaped aluminum powder, and any combination thereof. In some embodiments, the aluminum powder has a particle size, d₅₀ of 1-10 microns, or 2-8 microns. In some embodiments, the aluminum powder is a mixture of aluminum powders of different particle sizes. For example, aluminum powder having a particle size, d₅₀ in the range of 1-3 microns can be mixed with an aluminum powder having a particle size, d₅₀ in the range of 5-10 microns. The aluminum powder is present in the aluminum paste in an amount ranging from 42-85% or 46-85% by weight, based on the total weight of the silicon-free aluminum paste composition. Furthermore, the amount of aluminum powder in the silicon-free aluminum paste composition is such that the weight ratio of aluminum powder to the additive in the silicon-free aluminum paste composition is in the range of 5:1 to 999:1.

In one embodiment, the aluminum powders have aluminum content in the range of 99.5-100 weight %. In one embodiment, the aluminum powders further comprise other particulate metal(s), for example silver or silver alloy powders. The proportion of such other particulate metal(s) can be from 0.01-10%, or from 1-9% by weight, based on the total weight of the aluminum powder including particulate metal(s).

All statements made in the present description and the claims in relation to average particle sizes relate to average particle sizes of the relevant materials as are present in the aluminum paste composition as supplied to the user or customer.

In some embodiments, the aluminum paste composition also comprises optional additive at a concentration of 0.1-9%, or 0.25-6%, or 0.5-3% by weight, based on the total weight of the aluminum paste composition.

Suitable optional additive include glass frits, amorphous silicon dioxide, zinc or tin organometallic compounds, boron nitride, metal salts, and mixtures thereof. In an embodiment, the aluminum paste composition further includes at least one glass frit as an inorganic binder. The glass frit can include PbO. Alternatively, the glass frit can be lead-free. The glass frit can comprise components which, upon firing, undergo recrystallization or phase separation and form a frit with a separated phase that has a lower softening point than the original softening point. The softening point (glass transition temperature) of the glass frit can be determined by differential thermal analysis (DTA), and is typically in the range of about 325-800° C.

The glass frits typically have a particle size, d₅₀ in the range of 0.1-20 microns or 0.5-10 microns. In an embodiment, the glass frit can be a mixture of two or more glass frit compositions. In another embodiment, each glass frit of the mixture of two or more glass frit compositions can have different particle sizes, d₅₀. The glass frit can be present in an amount ranging from 0.01-5%, or 0.1-2%, or 0.2-1.25% by weight, based on the total weight of the aluminum paste composition.

Examples of suitable glass frits include borosilicate and aluminosilicate glasses. Glass frits can also comprise one or more oxides, such as B₂O₃, Bi₂O₃, SiO₂, TiO₂, Al₂O₃, CdO, CaO, MgO, BaO, ZnO, Na₂O, Li₂O, Sb₂O₃, PbO, ZrO₂, and P₂O₅.

In an embodiment, the aluminum paste compositions may comprise amorphous silicon dioxide in the form of a finely divided powder. In an embodiment, the amorphous silicon dioxide powder has a particle size, d₅₀ of 5-1000 nm or 10-500 nm, as measured using any suitable technique, such as, laser light scattering. In some embodiments, the amorphous silicon dioxide is a synthetically produced silica, for example, pyrogenic silica or silica produced by precipitation.

Amorphous silicon dioxide can be present in the aluminum paste composition in the range of 0.001-0.5%, or 0.01-0.5%, or 0.05-0.1% by weight, based on the total weight of the aluminum paste composition.

The aluminum pastes of the present invention may comprise zinc and/or tin organometallic compounds. Suitable zinc and tin organometallic compound includes zinc neodecanoate, tin octoate, and mixtures thereof. The zinc and/or tin organometallic compound and mixtures thereof can be present in the aluminum paste composition in the range of 0.001-3%, or 0.01-2%, or 0.05-1% by weight, based on the total weight of the aluminum paste composition.

Suitable boron nitride includes amorphous boron nitride, cubic boron nitride, hexagonal boron nitride, and mixtures thereof. The boron nitride can be present in the aluminum paste composition in the range of 0.01-7%, or 0.05-5%, or 0.1-3% by weight, based on the total weight of the aluminum paste composition.

Specific example of optional metal salt include bismuth phosphate. The metal salt can be present in the aluminum paste composition in the range of 0.1-7.0%, or 0.5-5.0%, or 1.0-3.0% by weight, based on the total weight of aluminum paste composition.

The total solid content of the aluminum paste composition, including an additive, aluminum powder, and an optional additive, is in the range of 30-90%, or 50-85% by weight, based on the total weight of the aluminum paste composition. Furthermore, the solid content of the aluminum paste composition comprises an additive present in an amount of 0.01-15% or 0.1-7%, aluminum powder present in an amount of 85-99.9% or 93-99.9%, and optional additive present in an amount of 0.1-9% or 0.5-3% by weight, wherein the solid content includes an additive comprising a salt of an alkaline earth metal ion and an organic counterion, aluminum powder, and other optional additive(s). Additionally, the weight ratio of aluminum powder to the additive in the aluminum paste composition is in the range of 5:1 to 999:1.

The solid content of the aluminum paste composition is dispersed in an organic vehicle. In some embodiments, the aluminum pastes of the present invention comprise an organic vehicle at a concentration of 9.9-70% or 9.9-57.9% or 9.9-49.9% by weight, based on the total weight of the aluminum paste composition. The amount of organic vehicle in the aluminum paste composition is dependent on several factors, such as the method to be used in applying the aluminum paste and the chemical constituents of the organic vehicle used. Organic vehicle includes one or more of solvents, binders, surfactants, thickeners, rheology modifiers, and stabilizers to provide one or more of: stable dispersion of insoluble solids; appropriate viscosity and thixotropy for application, in particular, for screen printing; appropriate wettability of the silicon substrate and the paste solids; a good drying rate; and good firing properties. Suitable organic vehicles include organic solvents, organic acids, waxes, oils, esters, and combinations thereof. In some embodiments, the organic vehicle is a nonaqueous inert liquid, an organic solvent, or an organic solvent mixture, or a solution of one or more organic polymers in one or more organic solvents. Suitable organic polymers include ethyl cellulose, ethylhydroxyethyl cellulose, wood rosin, phenolic resins, poly (meth)acrylates of lower alcohols, and combinations thereof. Suitable organic solvents include ester alcohols and terpenes such as alpha- or beta-terpineol and mixtures thereof with other solvents such as kerosene, dibutylphthalate, diethylene glycol butyl ether, diethylene glycol butyl ether acetate, hexylene glycol, high boiling alcohols, and mixtures thereof. The organic vehicle can also comprise volatile organic solvents for promoting rapid hardening after deposition of the aluminum paste on the back-side of the silicon wafer. Various combinations of these and other solvents can be formulated to obtain the desired viscosity and volatility.

The aluminum paste compositions are typically viscous compositions and can be prepared by mechanically mixing the aluminum powder, the additive, and the optional additive(s) with the organic vehicle. In one embodiment, the manufacturing method of high shear power mixing is used. In other embodiments, roll milling or other high shear mixing techniques are used.

The aluminum pastes of the present invention may be used in the manufacture of aluminum back electrodes of silicon solar cells or respectively in the manufacture of silicon solar cells.

As used herein, the phrase “silicon solar cell” is used interchangeably with “solar cell”, “cell”, “silicon photovoltaic cell”, and “photovoltaic cell”.

FIGS. 1A-1F schematically illustrate a process of forming a silicon solar cell in accordance with various embodiments of this invention. The process of forming a silicon solar cell comprises providing a p-type silicon substrate, 10, as shown in FIG. 1A. The silicon wafer can be a monocrystalline silicon wafer or a polycrystalline silicon wafer. The silicon wafer, 10 can have a thickness from 100-300 microns. However, the aluminum pastes of the present invention can be used for the production of aluminum back electrodes on the back-side of silicon wafers that are larger and/or having a lower thickness, for example, silicon wafers having a thickness below 180 μm, in particular in the range of 120 to below 180 μm and/or an area in the range of above 250 to 400 cm².

In FIG. 1B, an n-type diffusion layer, 20, of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer, 20 is formed over the entire surface of the silicon substrate, 10. The p-n junction is formed where the concentration of the p-type dopant equals the concentration of the n-type dopant; conventional cells that have the p-n junction close to the sun side, have a junction depth between 0.05-0.5 microns.

After the formation of this diffusion layer, 20 excess surface glass is removed from the rest of the surfaces by etching by an acid such as hydrofluoric acid, as shown in FIG. 1C.

Next, an antireflective coating (ARC), 30, is formed on the n-type diffusion layer, 20, to a thickness of between 0.05-0.1 microns in the manner shown in FIG. 1D by a process, such as, for example, plasma chemical vapor deposition (CVD).

As shown in FIG. 1E, a front-side silver paste (front electrode-forming silver paste), 500, for the front electrode is screen printed and then dried over the antireflective coating, 30. In addition, a back-side silver or silver/aluminum paste, 70, and an aluminum paste, 60, are then screen printed (or some other application method) and successively dried on the back-side of the substrate, 10. Normally, the back-side silver or silver/aluminum paste, 70 is screen printed onto the silicon first as two parallel strips (busbars) or as rectangles (tabs) ready for soldering interconnection strings (presoldered copper ribbons), the aluminum paste is then printed in the bare areas with a slight overlap over the back-side silver or silver/aluminum. In some cases, the silver or silver/aluminum paste, 70 is printed after the aluminum paste, 60 has been printed. The aluminum paste compositions disclosed hereinabove can be applied such that the wet weight (i.e., weight of the solids and the organic vehicle) of the applied aluminum paste is in the range of 4-9.5 mg/cm² or 5.5-8 mg/cm², and the corresponding dry weight of the aluminum paste is the range of 3-7 mg/cm² or 4-6 mg/cm². Any suitable method can be used for the application of aluminum paste, 60 such as silicone pad printing or screen printing. In various embodiments, the application viscosity of the aluminum paste, 60 as disclosed hereinabove is in the range of 20-200 Pa·s, or 50-180 Pa·s, or 70-150 Pa·s, as measured at a spindle speed of 10 rpm at 25° C. by a utility cup using a Brookfield HADV-1 Prime viscometer (Brookfield Inc., Middleboro, Mass.) and #14 spindle. After application of the back-side aluminum paste, 60 to the back-side of the silicon wafer, it may be dried, for example, for a period of 1-120 min, or 2-100 min, or 5-90 minutes at a peak temperature in the range of 100-400° C. Any suitable method can be used for drying, including, for example making use of belt, rotary or stationary driers, in particular, IR (infrared) belt driers. The actual drying time and drying temperature depend on various factors, such as aluminum paste composition, thickness of the aluminum paste layer, and drying method. For example, for the same aluminum paste composition, the temperature range for drying in a box furnace can be in the range of 100-200° C., while for a belt furnace it can be in the range of 200-400° C. In some embodiments, the drying of the back-side aluminum paste, 60 and the front-side metal paste, 500 is done in a single step. In other embodiments, the drying of the back-side aluminum paste, 60 and the front-side metal paste, 500 is done sequentially following each step of application.

The process of forming a silicon solar cell further comprises firing the silicon wafer with front-side metal paste and back-side aluminum paste at a peak temperature in the range of 600-980° C. Firing is then typically carried out in a belt furnace for a period of 1-5 minutes with the wafer reaching a peak temperature in the range of 600-980° C. The front and back electrodes can be fired sequentially or co-fired.

Consequently, as shown in FIG. 1F, molten aluminum from the paste dissolves the silicon during the firing process and then on cooling forms a eutectic layer that epitaxially grows from the silicon base, 10, forming a p+ layer, 40, containing a high concentration of aluminum dopant. This layer is generally called the back surface field (BSF) layer, and helps to improve the energy conversion efficiency of the solar cell. A thin layer of aluminum is generally present at the surface of this epitaxial layer.

The aluminum paste is transformed by firing from a dried state, 60, to an aluminum back electrode, 61. The back-side silver or silver/aluminum paste, 70, is fired at the same time, becoming a silver or silver/aluminum back electrode, 71, as shown in FIG. 1F. During firing, the boundary between the back-side aluminum and the back-side silver or silver/aluminum assumes an alloy state, and is connected electrically as well. The aluminum electrode accounts for most areas of the back electrode, owing in part to the need to form a p+ layer, 40. Since soldering to an aluminum electrode is impossible, a silver or silver/aluminum back electrode is formed over portions of the back-side (often as 2-6 mm wide busbars) as an electrode for interconnecting solar cells by means of pre-soldered copper ribbon or the like. In addition, the front-side silver paste, 500, sinters and penetrates through the antireflective coating, 30, during firing, and is thereby able to electrically contact the n-type layer, 20. This type of process is generally called “firing through”. This fired through state is apparent in layer, 501 of FIG. 1F.

Firing happens in the presence of oxygen, in particular, in the presence of air. During firing the organic substance including non-volatile organic material and the organic portion not evaporated during the possible drying step may be removed, i.e. burned and/or carbonized, in particular, burned. The organic substance removed during firing includes organic solvent(s), possible organic polymer(s), possible organic additive(s) and the organic moieties of the one or more alkaline earth metal-organic compounds. The alkaline earth may remain as alkaline earth oxide and/or hydroxide after firing. In case the aluminum pastes comprise glass frit(s), there may be a further process taking place during firing, namely sintering of the glass frit(s).

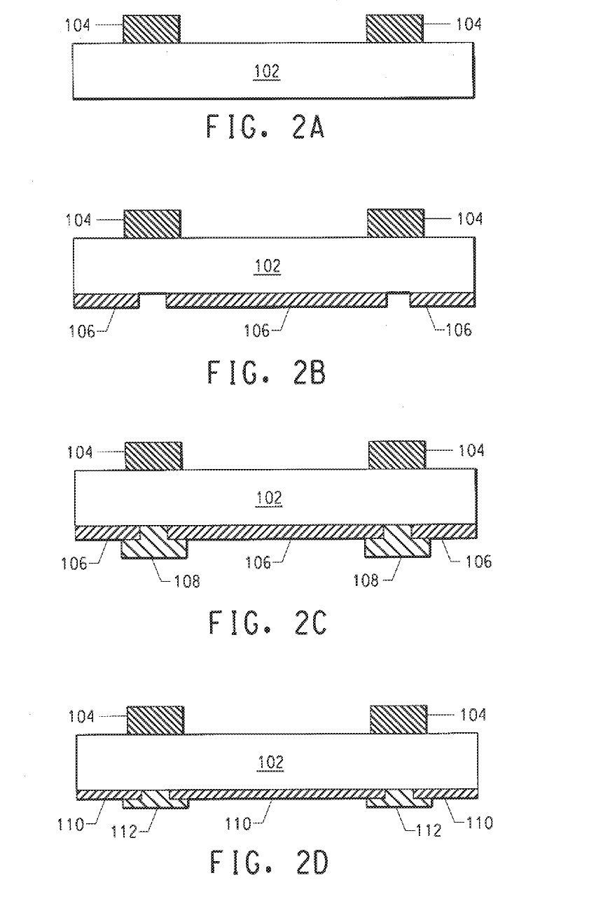

Next, a non-limiting example in which a silicon solar cell is prepared using an aluminum paste of the present invention is explained, referring to FIG. 2.

First, a silicon wafer substrate, 102 is prepared. On the light-receiving side face (front-side surface) of the silicon wafer, 102, normally with the p-n junction close to the surface, front-side electrodes (for example, electrodes mainly composed of silver) 104 are formed, as shown in FIG. 2A. On the back-side of the silicon wafer, a silver or silver/aluminum electroconductive paste, 108 (for example, PV202 or PV502 or PV583 or PV581, commercially available from E.I. Du Pont de Nemours and Company, Wilmington, Del.) is spread to form either busbars or tabs to enable interconnection with other solar cells set in parallel electrical configuration. On the back-side of the silicon wafer, a novel aluminum paste, 106 of the present invention used as a back-side (or p-type contact) electrode for a solar cell is spread by screen printing using the pattern that enable slight overlap with the silver or silver/aluminum paste referred to above, etc., then dried (FIG. 2B). Drying of the pastes is performed, for example, in an IR belt drier for a period of 1-10 minutes with the wafer reaching a peak temperature of 100-300° C. Also, the aluminum paste may have a dried film thickness of 15-60 μm, and the thickness of the silver or silver/aluminum paste may be 15-30 μm. Also, the overlapped part of the aluminum paste and the silver or silver/aluminum paste may be about 0.5-2.5 mm.

Next, the substrate obtained is fired, for example, in a belt furnace for a period of 1 to 5 minutes with the wafer reaching a peak temperature of 600-900° C., so that the desired silicon solar cell is obtained (FIG. 2D). An electrode 110 is formed from the aluminum paste wherein said paste has been fired to remove the organic substance and, in case the aluminum paste comprises glass frit, to sinter the latter.

The silicon solar cell obtained using the aluminum paste of the present invention, as shown in FIG. 2D, has metal front electrodes 104 on the light-receiving face (surface) or the sun-side of the silicon substrate 102, aluminum back electrodes 110 (formed by firing aluminum paste composition disclosed hereinabove) and silver or silver/aluminum electrodes 112 (formed by firing silver or silver/aluminum paste 108), on the back-side.

In an embodiment, the aluminum back electrode, 110 comprises 0.05-13.4% or 0.1-6% by weight of the additive and its decomposition product(s) and 86.6-99.95% or 94-99.9% by weight of aluminum, based on the total weight of the aluminum back electrode, 110.

In an embodiment, the aluminum back electrode, 110 further comprises 0.1-8% by weight of an optional additive, the optional additive comprising glass frits, decomposition products of tin and zin organometallic compounds, boron nitride, metal salts, and mixtures thereof.

In some embodiments, the use of the hereinabove disclosed aluminum paste compositions comprising an additive comprising a salt of an alkaline earth metal ion and an organic counterion, wherein the organic counterion is selected from the group consisting of carboxylates, phenylates, and resonates, in the production of aluminum back electrodes of silicon solar cells can result in silicon solar cells exhibiting reduction in cell bowing without impacting the cell efficiency (E_{ff}) and adhesion, as compared to solar cells formed using aluminum paste without any additive disclosed hereinabove. In an embodiment, the disclosed solar cells formed using the disclosed aluminum paste composition exhibit a reduction in bowing by at least 20% or by at least 30%, or by at least 40%, or by at least 50%, as compared to a solar cell formed using no additive. In an embodiment, the disclosed solar cells formed using the disclosed hereinabove aluminum paste composition with alkaline earth metal salt additive improve adhesion of the aluminum back electrode as compared to the solar cell formed using no additive.

As used herein, the terms “comprises,” “comprising,” “includes,” “including,” “has,” “having” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), or both A and B is true (or present).

As used herein, the phrase “one or more” is intended to cover a non-exclusive inclusion. For example, one or more of A, B, and C implies any one of the following: A alone, B alone, C alone, a combination of A and B, a combination of B and C, a combination of A and C, or a combination of A, B, and C.

Also, use of “a” or “an” are employed to describe elements and described herein. This is done merely for convenience and to give a general sense of the scope of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the disclosed compositions, suitable methods and materials are described below.

In the foregoing specification, the concepts have been disclosed with reference to specific embodiments. However, one of ordinary skill in the art appreciates that various modifications and changes can be made without departing from the scope of the invention as set forth in the claims below.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all embodiments.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

The concepts disclosed herein will be further described in the following examples, which do not limit the scope of the invention described in the claims.

The examples cited here relate to aluminum paste compositions used to form back-side contact in conventional solar cells.

The aluminum paste compositions can be used in a broad range of semiconductor devices, although they are especially effective in light-receiving elements such as photodiodes and solar cells. The discussion below describes how a solar cell is formed using the aluminum paste composition(s) disclosed herein, and how the solar cell is tested for cell bowing, cell efficiency, and paste adhesion.

Unless specified otherwise, compositions are given as weight percents.

### EXAMPLES

### Preparation of Back-Side Aluminum Paste Compositions

250 g to 1000 g of master batches of aluminum pastes A, B, C, D, and G were first made and small portions were taken out from the master batches to prepare exemplary additive pastes comprising alkaline earth metal salts (calcium carbonate, calcium, magnesium carbonate, calcium oxalate, and calcium octanoate).

### Preparation of Master Batch Aluminum Paste A

Two small batches of aluminum paste A with each batch of 268 g was made as follows and mixed together to get a larger batch from which the additive pastes were made.

First, a pre-wet aluminum slurry was made by mixing 80 weight % air-atomized nodular aluminum powder (greater than 99.7 weight % Al, having average particle size, d₅₀ of 6 microns) and 20 weight % organic vehicle 1 (OV1). OV1 included 43.5% terpineol solvent, 43.5% dibutyl carbitol, 7.5% oleic acid, and 5.5% ethyl cellulose (48.0%-49.5% ethoxyl content), by weight. Then, a pre-paste mixture was formed by mixing: 247.9 g of the pre-wet aluminum slurry with 6.7 g of organic vehicle 2 (OV2); 1.3 g of epoxidized octyl tallate; 0.8 g of polyunsaturated oleic acid; and 2.7 g of a mixture of wax and hydrogenated castor oil. OV2 included 46.7% terpineol solvent, 40.9% dibutyl carbitol, and 12.4% ethyl cellulose (49.6-51.5% ethoxyl content). The pre-paste mixture was further mixed using a planetary centrifugal mixer, THINKY ARE-310 (THINKY USA, Inc., Laguna Hills, Calif.) for 30 seconds at 2000 rpm. The mixing process was repeated for two more times to ensure uniform mixing to form a pre-paste. The pre-paste was then dispersed using a high shear mixer, Dispermat® TU-02 (VMA-Gwetzmann GMBH, Reichshof, Germany) at 1800 rpm to 2200 rpm for 3 minutes. The pre-paste was also stirred by hand to eliminate possible unmixed areas at the side, and the mixing with the Dispermat® TU-02 was repeated two more times to ensure uniformity. The second batch of similar quantity pre-paste was made following the same steps as above and two batches were combined together. The aluminum content of the combined pre-paste was then measured in duplicate by weighing small quantities (1-2 g) into an alumina boat and firing in a muffle furnace at 450° C. for 30 min to remove organics, and reweighing to obtain the residual aluminum weight. The combined pre-paste was found to have 76.82% aluminum by weight, which was above the desired range of 73-76% by weight, based on total weight of the aluminum paste composition. The viscosity of the combined pre-paste was measured using a Brookfield HADV-I Prime viscometer (Brookfield Engineering Laboratories, Inc., Middleboro, Mass.) with the thermostatted small-sample adapter at 10 rpm and was found to be 118 Pa·s. To achieve the desired weight % and viscosity range, 18.01 g of organic vehicle 3 (OV3) (a 50/50 blend of terpineol solvent and dibutyl carbitol) was added to the combined pre-paste and mixed again using Dispermat® to obtain the master batch paste A. The viscosity of the master batch paste A was measured the following day using a Brookfield HADV-I Prime viscometer with the thermally controlled small-sample adapter at 25° C. and was found to be 84 Pa·s at 10 rpm. The final solid content of the master batch paste A was found to be 73.78% by weight.

Master batch paste A was measured for fineness of grind (FoG) to qualify for the printability using gage #5251 (Precision Gage and Tool Co., Dayton, Ohio) with the specification range of 0-25 microns. A small amount (dot) of the master batch paste A was applied on both grooves of the gage at the 25 microns mark end. A scraper was placed above the dot and with high and uniform pressure, the paste was drawn down in a continuous band toward towards the 0 micron end. The readings of maximum particle size (beginning of fourth continuous scratch and the point where 50% of the band has been scratched away) on both sides grooves within 10 seconds of paste draw-down were measured to be under 50 microns and 20 microns respectively, thereby meeting the printability requirement.

### Preparation of Master Batch Aluminum Paste B

Two small batches (approximately 208 g each) of aluminum paste B were made as follows and mixed together to get a larger batch from which the additive pastes were made.

First, a pre-wet aluminum slurry was made by mixing 80 weight % air-atomized nodular aluminum powder (greater than 99.7 weight % Al, having average particle size of 6 microns) and 20 weight % organic OV1. Then, a pre-paste mixture was formed by mixing: 186.2 g of the pre-wet aluminum slurry with 2.09 g of zinc neodecanoate; 1.04 g of tin octoate; 2.71 g of organic vehicle 4 (OV4); 1.04 g of epoxidized octyl tallate; 0.63 g of polyunsaturated oleic acid; 2.09 g of a mixture of wax and hydrogenated castor oil; 0.146 g of amorphous silica; and 0.418 g of glass-frit. OV4 included 42.7% terpineol solvent, 42.7% dibutyl carbitol, and 14.6% ethyl cellulose (low molecular weight), by weight. Glass-frit included 38.9% SiO₂, 0.8% Al₂O₃, 22.1% PbO, 22.8% B₂O₃, 3.1% Bi₂O₃, 7.8% TiO₂, and 4.6% PbF₂, by weight. The pre-paste mixture was further mixed using a planetary centrifugal mixer, THINKY ARE-310 (THINKY USA, Inc., Laguna Hills, Calif.) for 30 seconds at 2000 rpm. The mixing process was repeated for two more times to ensure uniform mixing to form a pre-paste. The pre-paste was then dispersed using a high shear mixer, Dispermat® TU-02 (VMA-Gwetzmann GMBH, Reichshof, Germany) at 1800 rpm to 2200 rpm for 3 minutes. The pre-paste was also stirred by hand to eliminate possible unmixed areas at the side, and the mixing with the Dispermat® TU-02 was repeated two more times to ensure uniformity. The second batch of similar quantity pre-paste was made following the same steps as above and two batches were combined together. The aluminum content of the combined pre-paste was then measured in duplicate by weighing small quantities (1-2 g) into an alumina boat and firing in a muffle furnace at 450° C. for 30 minutes to remove organics, and reweighing to obtain the residual aluminum weight. The combined pre-paste was found to have 76.78% aluminum by weight which was above the desired range of 72-74% by weight, based on total weight of the aluminum paste composition. The viscosity of the combined pre-paste was measured using a Brookfield HADV-I Prime viscometer (Brookfield Engineering Laboratories, Inc., Middleboro, Mass.) with the thermostatted small-sample adapter at 10 rpm and was found to be 127 Pa·s. To achieve the desired weight % and viscosity range, 7.24 g of OV3 and 15.97 g of OV2 were added to the combined pre-paste and mixed again using Dispermat® to obtain the master batch paste B. The viscosity of the master batch paste B was measured the following day using a Brookfield HADV-I Prime viscometer with the thermally controlled small-sample adapter at 25° C. and was found to be 92.5 Pa·s at 10 rpm. The final solid content of the master batch paste B was found to be 72.34 weight %.

### Preparation of Master Batch Aluminum Paste C

Paste C was made similar to Paste A with similar ingredients and compositions except that the nitrogen-atomized spherical aluminum powder (average particle size 6 μm) was used instead of the air-atomized nodular aluminum powder.

### Preparation of Master Batch Aluminum Paste D

Paste D was made similar to Paste B with similar ingredients and compositions except that the nitrogen-atomized spherical aluminum powder (average particle size 6 μm) was used instead of the air-atomized nodular aluminum powder.

### Master Batch Aluminum Paste E

Paste E was a commercial aluminum paste, namely PV381 (E I DuPont Nemours Company, Wilmington, Del.) comprising 70-75 wt % aluminum, 10-15 wt % 2-(2-butoxyethoxy) ethanol, 10-15 wt % pine oil, according to the information disclosed in the MSDS sheet.

### Master Batch Aluminum Paste F

Pastes F was a commercial Al pastes, namely Ruxing RX8204 (Ruxing, Guangzhou City, Guangdong Province. China) comprising 60-76 wt % nitrogen-atomized spherical aluminum powder, 1-5 wt % 2-(2-Butoxyethoxy) ethanol, 15-20 wt % terpineol, 1-5 wt % methyl carbitol, according to the information disclosed in the MSDS sheet.

### Preparation of Master Batch Aluminum Paste G

Paste G was made similar to Paste B with similar ingredients and compositions except it was made without frit.

### Preparation of Additive Aluminum Pastes

Exemplary additive aluminum paste compositions comprising 1-9% of alkaline earth metal salts (calcium carbonate, calcium oxalate, calcium octanoate, and calcium magnesium carbonate), by weight, based on the total solid (aluminum and alkaline earth metal salt) content, were prepared using the master batch aluminum pastes A-G described supra. The additive aluminum pastes were prepared by replacing aluminum content in the paste whereas the control aluminum pastes comprised no addition of calcium compounds. For the paste containing calcium salts, the calcium salt concentration given in the tables therefore is based on total solid content (aluminum+calcium salt) of the aluminum paste composition.

Hence, an additive paste A comprising a 9 weight % calcium carbonate indicates that the aluminum:calcium carbonate weight ratio was 91:9 and the back-side aluminum paste comprised 67.14% aluminum and 6.64% calcium calcium carbonate, by weight, based on the final solid content of 73.78 weight % of the master batch aluminum paste A.

### Frit Preparation

50 g of glass frit of was made by heating a mixture of 23.11 g of bismuth(III) oxide, 8.89 g of silicon dioxide, 23.11 g of diboron trioxide, 6.20 g of antimony trioxide, and 3.91 g of zinc oxide in a platinum crucible to 1400° C. in air in a box furnace (CM Furnaces, Bloomfield, N.J.). The liquid was poured out of the crucible onto a metal plate to quench it. XRD analysis indicated that the frit was amorphous. The glass frit was milled in IPA using 5 mm YSZ balls with a jar mill, reducing the particles to a d50 of 0.53 microns.

### Formation of Solar Cell Wafers for Bowing Determination

For the cell bowing measurements, a rectangular cell design was chosen to amplify any observed bowing. Exemplary solar cell wafers for bowing measurements were fabricated using p-type polycrystalline silicon wafers having a thickness of 160 or 200 microns. The silicon wafers had a nominal base resistivity of 1 Ohm/sq, an emitter resistivity of 65 Ohm/sq, and a hydrogen-containing silicon nitride (SiNₓ:H) antireflective coating formed by plasma enhanced chemical vapor deposition (PECVD). The 152 mm×152 mm silicon wafers were cut into rectangular 14 mm×65 mm wafers using a diamond saw, and then cleaned.

Master batch aluminum pastes A-F and additive pastes prepared supra were printed onto the back-side of the rectangular silicon wafers using a screen (Sefar Inc., Depew, N.Y.) with a rectangular opening of 13 mm×64 mm and a screen printer, MSP 885 (Affiliated Manufacturers Inc., North Branch, N.J.). This left a nominal 0.5 mm border of bare Si (i.e., without Al) around the edges. Each wafer was weighed before and after the application of aluminum paste to determine a net weight of applied aluminum paste on the wafer. The wet weight of Al paste A was targeted to be 63 mg, which produced an Al loading after firing of 5.6 mg Al/cm². The aluminum paste A coated silicon wafers were dried in a mechanical convection oven with vented exhaust for 30 minutes at 150° C., resulting in a dried film thickness of 30 microns. No front-side paste was screen printed on silicon wafers used in the bow measurements.

The printed and dried rectangular silicon wafers were then fired in an IR furnace PV614 reflow oven (Radiant Technology Corp., Fullerton, Calif.) at a belt speed of 457 cm/minute (or 180 inch/minute). The furnace had six heated zones, and the zone temperatures used were zone 1 at 550° C., zone 2 at 600° C., zone 3 at 650° C., zone 4 at 700° C., zone 5 at 800° C., and the final heated zone 6 set at peak temperature in the range of 840-940° C. The wafers took 33 sec to pass through all of the six heated zones with 2.5 sec each in zone 5 and zone 6. The wafers reached peak temperatures lower than the zone 6 set, in the range of 740-840° C. The zone 6 set point temperature is the cell firing temperature referred to in Tables 1-4.

### Bowing Measurement of the Solar Cell Wafers

A jig was made to facilitate easy and accurate cell bowing measurement of solar cell wafers prepared supra. The jig consisted of a 30.48 cm×30.48 cm table, with legs of 15.24 cm. The table top was flat, and had 1 cm hole in the middle. To facilitate the measurement, the hole was tapered so that the hole size on the bottom of the table top was larger than the hole size on the top. The measurement head of a Keyence LC-2001 (Mississauga, Ontario, CANADA) Laser Displacement Meter was mounted to the underside of the table top held by a micrometer driven translation stage. The laser displacement meter's light beam projected straight upward through the hole in the table top. The flat surface of the table top is used as the reference plane for the bow measurement. Prior to taking measurements the vertical location of the LC-2001 was adjusted with the micrometer driven translation stage such that the meter read zero when a known flat sample was placed on the table top over the hole. Then, a solar cell wafer prepared supra was placed on the table top such that its center was centered over the hole. The LC-2001 then reads out the displacement from the table top flat surface in microns with accuracy of ±1 micron (i.e. ±0.001 mm).

Table 1 summarizes the bow results of using pastes A to F printed on 160 μm thick wafer. Table 2 summarizes the bow results of using pastes A and B printed on 200 μm thick wafer.

TABLE 1
Bowing characteristics of exemplary solar cell wafers (160
microns thick)

| | | | Median | % |
|---|---|---|---|---|
| | | | Solar | Decrease |
| | | | Cell | in Solar |
| | Back-side Paste | Firing | Wafer | Cell |
| | (weight % based on | Temperature | Bowing | Wafer |
| Example # | the total solid content) | (° C.) | (mm) | Bowing |
| Control 1 | Paste A | 875 | 0.432 | |
| 1.1 | Paste A with 3% calcium | 875 | 0.273 | 37% |
| | carbonate | | | |
| 1.2 | Paste A with 1% calcium | 875 | 0.341 | 21% |
| | oxalate | | | |
| 1.2 | Paste A with 3% calcium | 875 | 0.275 | 36% |
| | oxalate | | | |
| 1.3 | Paste A with 9% calcium | 875 | 0.222 | 49% |
| | oxalate | | | |
| 1.4 | Paste A with 1% calcium | 875 | 0.299 | 31% |
| | magnesium carbonate | | | |
| 1.5 | Paste A with 3% calcium | 875 | 0.222 | 49% |
| | magnesium carbonate | | | |
| 1.6 | Paste A with 9% calcium | 875 | 0.163 | 62% |
| | magnesium carbonate | | | |
| 1.7 | Paste A with 5% calcium | 875 | 0.333 | 23% |
| | octanoate | | | |
| 1.8 | Paste A with 15% | 875 | 0.241 | 44% |
| | calcium octanoate | | | |
| Control 2 | Paste B | 875 | 0.308 | |
| 2.1 | Paste B with 3% calcium | 875 | 0.204 | 34% |
| | carbonate | | | |
| Control 3 | Paste C | 900 | 0.463 | |
| 3.1 | Paste C with 3% calcium | 900 | 0.31 | 33% |
| | carbonate | | | |
| 3.2 | Paste C with 9% calcium | 900 | 0.228 | 51% |
| | carbonate | | | |
| Control 4 | Paste D | 900 | 0.176 | |
| 4.1 | Paste D with 3% calcium | 900 | 0.135 | 23% |
| | carbonate | | | |
| 4.2 | Paste D with 9% calcium | 900 | 0.127 | 28% |
| | carbonate | | | |
| Control 5 | Paste E | 860 | 0.461 | |
| 5.1 | Paste E with 3% calcium | 860 | 0.419 | 9% |
| | carbonate | | | |
| 5.2 | Paste E with 9% calcium | 860 | 0.325 | 30% |
| | carbonate | | | |
| Control 6 | Paste F | 860 | 0.42 | |
| 6.1 | Paste F with 3% calcium | 860 | 0.264 | 37% |
| | carbonate | | | |
| 6.2 | Paste F with 9% calcium | 860 | 0.212 | 50% |
| | carbonate | | | |

TABLE 2
Bowing characteristics of exemplary solar cell wafers (200
microns thick)

| | | | Median | % |
|---|---|---|---|---|
| | | | Solar | Decrease |
| | | | Cell | in Solar |
| | Back-side Paste | Firing | Wafer | Cell |
| | (weight % based on the | Temperature | Bowing | Wafer |
| Example # | total solid content) | (° C.) | (mm) | Bowing |
| Control 7 | Paste A | 875 | 0.235 | |
| 7.1 | Paste A with 3% calcium | 875 | 0.146 | 38% |
| | carbonate | | | |
| Control 8 | Paste B | 875 | 0.149 | |
| 2.1 | Paste B with 3% calcium | 875 | 0.124 | 17% |
| | carbonate | | | |

As can be seen from Tables 1 and 2, addition of up to 9 weight % of calcium salt of carbonate, oxalate, or octanoate to the aluminum paste A-F resulted in up to 62% reduction in solar cell wafer bowing compared to the control pastes A-F without calcium salt additive, irrespective of the silicon wafer thickness. Increasing the amount of calcium salt additive from 1% to 9% resulted in a corresponding decrease in bowing.

### Formation of Solar Cells for and the Evaluation of the Electrical Performance of Solar Cells

Exemplary solar cells for measurement of electrical performance and SEM analysis were fabricated starting with p-type polycrystalline silicon wafers having a thickness of 160 microns. The 28 mm×28 mm cells were cut and prepared following a similar procedure to that described supra for the formation of solar cell wafers.

Aluminum pastes A, B, and C and additive pastes A, B, and C containing various amounts of calcium oxide, prepared supra were printed onto the back-side of the silicon wafers using a screen (Sefar Inc., Depew, N.Y.) with a square opening of 26.99 mm×26.99 mm and a screen printer, MSP 885 (Affiliated Manufacturers Inc., North Branch, N.J.). This left a nominal 0.5 mm border of bare Si (i.e., without Al) around the edges. Each wafer was weighed before and after the application of aluminum paste to determine a net weight of applied aluminum paste on the silicon wafer. The wet weight of Al paste A was targeted to be 55 mg, which produced an Al loading after firing of 5.6 mg Al/cm². The wet print weight for paste B and paste C were adjusted accordingly to obtain the target weight of 5.6 mg Al/cm² after firing. The aluminum paste was dried in a mechanical convection oven with vented exhaust for 30 minutes at 150° C., resulting in a dried film thickness of 30 microns.

Then, a silver paste Solamet® PV145 (E. I. du Pont de Nemours and Company, Wilmington, Del.) was screen printed on the silicon nitride layer on the front surface of the silicon wafer using screens on 20.3 cm×25.4 cm (8″×10″) frames (Sefar Inc., Depew, N.Y.) and a screen printer model MSP 485 (Affiliated Manufacturers Inc., North Branch, N.J.). The printed wafers were dried at 150° C. for 20 minutes in a convection oven to give 20-30 microns-thick silver grid lines and a bus bar. The screen printed silver paste had a pattern of eleven grid lines of 100-140 microns width connected to a bus bar of 1.25 mm width located near one edge of the cell.

The printed and dried silicon wafers were then fired in an IR furnace PV614 reflow oven (Radiant Technology Corp., Fullerton, Calif.) at a belt speed of 457 cm/minute (or 180 inch/minute). The furnace had six heated zones, and the zone temperatures used were zone 1 at 550° C., zone 2 at 600° C., zone 3 at 650° C., zone 4 at 700° C., zone 5 at 800° C., and the final heated zone 6 set at peak temperature in the range of 840-940° C. The wafers took 33 sec to pass through all of the six heated zones with 2.5 sec each in zone 5 and zone 6. The wafers reached peak temperatures lower than the zone 6 set, in the range of 740-840° C. The zone 6 set point temperature is the cell firing temperature referred to in Table 3. After firing, the metalized wafer became a functional solar cell.

All control, exemplary, and comparative solar cells were made in groupings denoted as “series”. Within a series, all cells were printed with the aluminum pastes and the silver pastes on the same day, and all cells were fired together on the same day.

Each aluminum paste composition gave an efficiency which became maximized at a firing temperature which might be different for the different paste compositions. For each aluminum paste composition within a series, a number of duplicate solar cells were fabricated. These solar cells were then divided into 3 or 4 groups, and all the solar cells in each group (typically 3 to 6 wafers per group) were fired at the same temperature. The firing temperatures for the different groups were in the range of 850° C. to 925° C. at about 25° C. increment. For each firing temperature, the median efficiency of the solar cells in that group was determined and reported in the Table 3.

### Evaluation of the Electrical Performance of Solar Cells

A commercial Current-Voltage (JV) tester ST-1000 (Telecom-STV Ltd., Moscow, Russia) was used to make efficiency measurements of the polycrystalline silicon solar cells prepared supra. Two electrical connections, one for voltage and one for current, were made on the top and the bottom of each of the solar cells. Transient photo-excitation was used to avoid heating the silicon solar cells and to obtain JV curves under standard temperature conditions (25° C.). A flash lamp with a spectral output similar to the solar spectrum illuminated the solar cells from a vertical distance of 1 m. The lamp power was held constant for 14 milliseconds. The intensity at the sample surface, as calibrated against external solar cells was 1000 W/m² (or 1 Sun) during this time period. During the 14 milliseconds, the JV tester varied an artificial electrical load on the sample from short circuit to open circuit. The JV tester recorded the light-induced current through, and the voltage across, the solar cells while the load changed over the stated range of loads. A power versus voltage curve was obtained from this data by taking the product of the current times the voltage at each voltage level. The maximum of the power versus voltage curve was taken as the characteristic output power of the solar cell for calculating solar cell efficiency. This maximum power was divided by the area of the sample to obtain the maximum power density at 1 Sun intensity. This was then divided by 1000 W/m² of the input intensity to obtain the efficiency which is then multiplied by 100 to present the result in percent efficiency. Other parameters of interest were also obtained from this same current-voltage curve. Of special interest were: the open circuit voltage (U_{oc}), which is the voltage where the current is zero; the short circuit current (I_{sc}), which is the current when the voltage is zero, and, for reasonably efficient cells, estimates of the series (Rₐ) and shunt (Rₛₕ) resistances were obtained from the reciprocal of the local slope of the current voltage curve near the short circuit and open circuit points, respectively. The cell bowing along with cell efficiency results are summarized in Table 3.

TABLE 3
Bowing characteristic and Cell Efficiency of Solar Cell Wafers

| | Back-side | | | |
|---|---|---|---|---|
| | Paste | | | |
| | (weight % | | Median | |
| | based on | | Solar Cell | |
| | the total | | Wafer | Median Cell |
| | solid | Firing Temperature | Bowing | Eddiciency |
| Example # | content) | (° C.) | (mm) | (%) |
| Control 9 | Paste A | 870 | 0.432 | 16.42 |
| 9.1 | Paste A with | 870 | 0.016 | 16.54 |
| | 3% CaCO₃ | | | |
| Control 10 | Paste B | 870 | 0.191 | 16.44 |
| 10.1 | Paste B with | 870 | 0.25 | 16.5 |
| | 3% CaCO₃ | | | |

Table 3 shows the median cell efficiency and median bowing for the cells fired at a specified temperature. It should be noted that these cells were not optimized for optimum cell efficiency performance with various cell firing temperature profile which is outside the scope of the present invention, which is limited to cell bowing and adhesion.

### Paste Adhesion Test

Aluminum pastes need to have good adhesion to the silicon wafer to qualify for commercial application. Hence, cohesive strength of the Al metallization formed using exemplary aluminum paste compositions was tested using a peel test on solar cells fabricated as described above. To this end a transparent layer of adhesive tape was applied to tared samples of 1.05″×1.05″ cells. The tape was applied using a tared aluminum foil template to define the area of contact with the wafer (0.78 cm²). The tape was subsequently peeled off and both the wafer and the tape were re-weighed using an analytical balance (Mettler MT5, Columbus, Ohio). The weight differences of both wafer and the tape are shown in Table 4 as mean values of four separate measurements. Table 4. Adhesion test results based on weight measurements.

| | | | | Mean | Mean |
|---|---|---|---|---|---|
| | Back-side Paste | | | weight | weight |
| | (weight % | | | loss in | gain in |
| | based on | Firing | | wafer, | tape, |
| | the total | Temperature | | micro- | micro- |
| Example # | solid content) | (° C.) | Adhesion | gram | gram |
| Control 11 | Paste B | 900 | Moderate | −89 | +99 |
| Example | Paste B with | 875 | Improved | −8 | +78 |
| 11.1 | 3% CaCO₃ | | | | |
| Control 12 | Paste G | 900 | Poor | −856 | +920 |
| Example | Paste G with | 900 | Improved | −343 | +346 |
| 12.1 | 3% CaCO₃ | | | | |

As can be seen in Table 4, the presence of 3 weight % calcium carbonate in the aluminum paste compositions improved the adhesion in comparison to the aluminum paste containing no calcium carbonate additive.

### Decomposition of CaCO₃ Additive

### Example 13.1

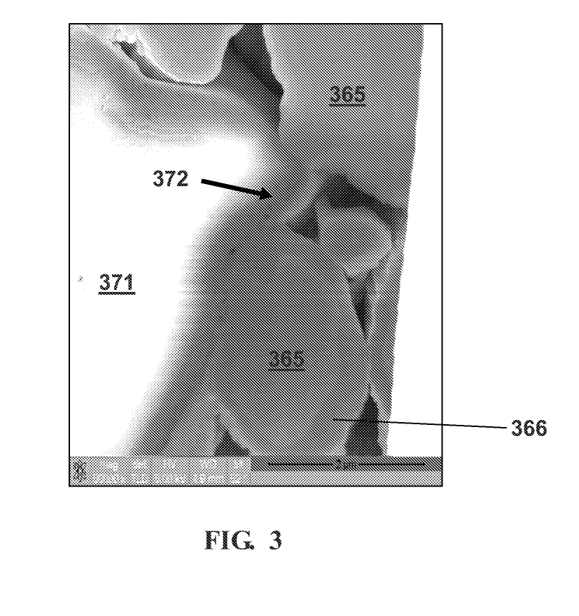

An additive paste was made using master batch aluminum paste A and calcium carbonate powder was added such as to give 5% of CaCO₃ in the paste solids. A 28 mm×28 mm solar cell was fabricated using this paste on the back side, and the cell was fired at 925° C. A cross-section sample from the particulate layer of the aluminum back electrode was made using the focused ion beam method. FIG. 3 shows an SEM image of the cross-section, including two aluminum particles, 365 and silicon particles, 366. Electron diffraction with a TEM beam was also done on the particulate layer. This allowed identification of the core of the particle, 371 on the left of the image shown in FIG. 3, as calcium carbonate, which is the same composition as the additive. However the shells of the calcium carbonate additive had decomposed during or subsequent to firing to form either calcium oxide or calcium hydroxide, 372. The diffraction patterns allowed differentiation of the CaCO₃ core from the shell, but were insufficient to distinguish between CaO and Ca(OH)₂ in the shell. A portion of the decomposition product CaO/Ca(OH)₂ is located at the interface between the two aluminum particles.

What is claimed is:

1. An aluminum paste composition comprising:
a) 0.050-12.7% by weight of an additive, the additive comprising a salt of an alkaline earth metal ion and an organic counterion, wherein the organic counterion is selected from the group consisting of carboxylates, phenylates, and resonates;
b) 42-85% by weight of an aluminum powder, such that the weight ratio of aluminum powder to the additive is in the range of 5:1 to about 999:1; and
c) an organic vehicle;
wherein the amounts in % by weight are based on the total weight of the aluminum paste composition.

2. The aluminum paste composition of claim 1, wherein the additive is present in an amount ranging from 0.05-6% by weight.

3. The aluminum paste composition of claim 1, wherein the aluminum powder is present in an amount ranging from 46-85% by weight.

4. The aluminum paste composition of claim 1, further comprising 0.1-9% by weight of an optional additive selected from the group consisting of glass frits, amorphous silicon dioxide, organometallic compounds, boron nitride, metal salts, and mixtures thereof.

5. The aluminum paste composition of claim 4, wherein the glass frit is present in an amount ranging from 0.01-5% by weight.

6. A solar cell comprising:
(a) a p-type silicon substrate comprising a p-type region sandwiched between an n-type region and a p+ layer;
(b) an aluminum back electrode disposed on the p+ layer, wherein the aluminum back electrode comprises 0.05-13.4% by weight of an additive and its decomposition products(s), the additive comprising a salt of an alkaline earth metal ion and an organic counterion and 86.6-99.95 by weight of aluminum, based on the total weight of the aluminum back electrode,
wherein the organic counterion is selected from the group consisting of carboxylates, phenylates, and resonates, and
wherein the decomposition products of the additive comprises alkaline earth metal oxide and alkaline earth metal hydroxide; and
(c) a metal front electrode disposed over a portion of the n-type region.

7. The solar cell of claim 6, wherein the aluminum back electrode comprises 0.1-6% of the additive and its decomposition products(s), by weight.

8. The solar cell of claim 6, wherein the aluminum is present in an amount ranging from 94-99.9% by weight.

9. The solar cell of claim 6, wherein the aluminum back electrode further comprises 0.1-8% by weight of an optional component, the optional component comprising amorphous silicon dioxide, zinc organometallic additive, tin organometallic additive, one or more glass frit compositions, or mixtures thereof.

10. The solar cell of claim 6, further comprising an antireflective coating (ARC) layer disposed on the n-type region.

11. A process of forming a silicon solar cell comprising:
(a) applying an aluminum paste composition on a back-side of a p-type silicon substrate, the aluminum paste composition comprising:
(i) 0.05-12.7% by weight of an additive, the additive comprising a salt of an alkaline earth metal ion and an organic counterion, wherein the organic counterion is selected from the group consisting of carboxylates, phenylates, and resonates,
(ii) 42-85% by weight of an aluminum powder, such that the weight ratio of aluminum powder to the additive is in the range of 5:1 to about 999:1, and
(iii) an organic vehicle;
wherein the amounts in % by weight are based on the total weight of the aluminum paste composition;
(b) applying a metal paste on a front-side of the p-type silicon substrate, the front-side being opposite to the back-side; and
(c) firing the p-type silicon substrate after the application of the aluminum paste at a peak temperature in the range of 600-980° C.

12. The process of forming a silicon solar cell according to claim 11, wherein the salt of an alkaline earth metal ion and an organic counterion is present in the aluminum paste composition in an amount ranging from 0.1-6% by weight.

13. The process of forming a silicon solar cell according to claim 11, wherein the aluminum powder is present in the aluminum paste in an amount ranging from 46-85% by weight.

14. The process of forming a silicon solar cell according to claim 11, wherein the step (c) of firing the p-type silicon substrate after the application of the aluminum paste is done after the step (b) of applying a metal paste on a front-side of the p-type silicon substrate.

15. A silicon solar cell made by the process of claim 12.
